(19) United States
(12) Patent Application Publication
(10) Pub. No.: US 2024/0071977 A1
(43) Pub. Date: Feb. 29, 2024

(54) DIE EDGE FILLET AND 3D-PRINTED CNT AS BENDING STRESS BUFFER

(71) Applicant: Micron Technology, Inc., Boise, ID (US)

(72) Inventors: Chen Yu Huang, Taichung City (TW); Chong Leong Gan, Taichung City (TW)

(21) Appl. No.: 17/823,189

(22) Filed: Aug. 30, 2022

(51) Int. Cl. H01L 23/00; H01L 23/24; H01L 25/00; H01L 25/065

(52) U.S. Cl. CPC H01L 24/33; H01L 23/24; H01L 24/29; H01L 24/32; H01L 24/83; H01L 25/0657; H01L 25/50; H01L 23/3128; H01L 2224/2919; H01L 2224/32145; H01L 2224/32225; H01L 2224/3303; H01L 2224/33181; H01L 2224/33183; H01L 2224/33505; H01L 2224/83191; H01L 2224/83193; H01L 2224/83855; H01L 2924/0665

(57) ABSTRACT

A semiconductor package having a fillet is provided. The semiconductor package includes a trace disposed within a solder mask that has a top surface. A first die is over the solder mask and mechanically couples with the trace. A first adhesive is between the trace and the first die where sides of the first die and the first adhesive define a die edge. The semiconductor package includes a fillet adjacent the die edge and a second die above the first die. The semiconductor package also includes a second adhesive having a bottom surface where the second adhesive is between the first die and the second die. The solder mask top surface, the first die surface, and the second adhesive bottom surface define a cavity where the fillet is within the cavity at the die edge.

### TECHNICAL FIELD

Examples of the present disclosure relate generally to semiconductor devices and more specifically to structures and methods for increasing a robustness of semiconductor devices.

### BACKGROUND

Semiconductor devices can include memory packaging formed in a substrate that can be used with a die having a functional circuit. The memory packaging can include semiconductor packages that can interface with the functional circuit die. An adhesive can bond the memory package substrate with the functional circuit die. The memory package can include copper traces that can interface with the functional circuit die. Occasionally, cracks can occur at one of the copper traces within the substrate near an edge of the adhesive used to bond the functional circuit die with the memory package.

### BRIEF DESCRIPTION OF THE DRAWINGS

Various ones of the appended drawings merely illustrate example embodiments of the present disclosure and should not be considered as limiting its scope.

FIG. 1 illustrates a semiconductor package in accordance with some examples.

FIGS. 2 and 3 illustrate cracking that can occur in a semiconductor package due to different CTEs and the different modulus of elasticities among different materials used in the semiconductor package.

FIGS. 4-11 illustrate a method for forming the semiconductor device of FIG. 1 with a capillary underfill in accordance with some examples.

FIGS. 12-15 illustrate a method of forming a semiconductor device with a carbon nanotube in accordance with some examples.

FIG. 16 illustrates stress-strain curves where a modulus of elasticity of the fillet formed with various levels of carbon nanotubes is compared with a trace line formed of copper.

### DETAILED DESCRIPTION

The description that follows includes systems, methods, techniques, instruction sequences, and computing machine program products that embody illustrative embodiments of the disclosure. In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, protocols, structures, and techniques are not necessarily shown in detail.

Examples relate to a semiconductor package that includes a conductive trace line disposed in a solder mask and a first die adhered to the solder mask and mechanically coupled with the trace line via a first adhesive. The first die can include a first die side and the first adhesive can include a first adhesive side where the first die side and the first adhesive side together can define a die edge. The semiconductor device can also include a second die over the first die where a second adhesive is disposed between the first die and the second die. The second adhesive can include a bottom surface, where the second adhesive bottom surface in combination with the first die side and a top surface of the first adhesive can define a cavity. In examples, the semiconductor package can include a fillet disposed within the cavity. In examples, the fillet can help prevent fracture or cracking of the trace line. In some examples, the fillet can be a capillary underfill formed from an epoxy and fine fillers or can include a carbon nanotube-containing material.

In examples where the fillet is a capillary underfill and formed from epoxy, fillet material corresponding to the capillary underfill can be dispensed at the die edge. After dispensing the fillet material, the second adhesive and the second die can be placed over the first die. In examples, the fillet material can extend from the first adhesive top surface along the first die side surface and to the second adhesive bottom surface via capillary action. Therefore, through capillary action, the fillet material can fill a portion of the cavity, and a curing process can be performed to form the shape of fillet material. In some examples, the fillet can fill the entire cavity.

In further examples, the second adhesive and the second die can be placed over the first die. After combining the first and second dies using the second adhesive, the fillet material can be dispensed at the die combination edge. Moreover, through capillary action, the fillet material can extend from the first adhesive top surface along the first die side surface and to the second adhesive bottom surface thereby filling a portion of the cavity. After a curing process, the fillet can be formed. In some examples, the fillet material can fill the entire cavity.

In an example, the fillet can comprise a fillet material including a carbon nanotube. In this example, after attaching the first die on the solder mask surface using a first adhesive, the fillet material can be dispensed at the die edge. The dispensed material can include a liquid with carbon nanotube material. In some examples, the carbon nanotube material can also be dispensed onto the first adhesive top surface and along the first side surface. The carbon nanotube material can then be allowed to dry, thereby forming the fillet.

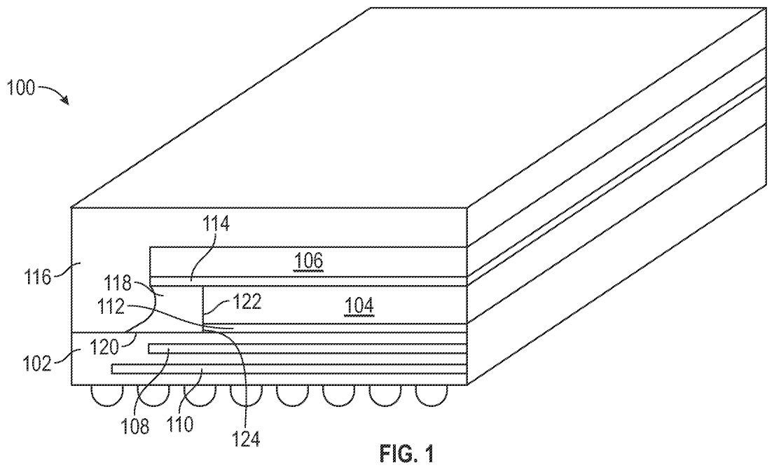

To further illustrate examples, reference is now made to FIG. 1, where a semiconductor package 100 is shown that can be a NOT-AND (NAND) package or a dynamic random-access memory (DRAM) package. The semiconductor package 100 can include a solder mask 102 along with a first die 104 and a second die 106 disposed over or directly on the solder mask 102. It should be noted that throughout this document, reference will be made to the first die 104 and the die 104. The terms first die 104 and die 104 are interchangeable with each other. Moreover, throughout this document, reference will be made to the second die 106 and the die 106. The terms second die 106 and die 106 are interchangeable with each other. The solder mask 102 can include various conductive trace lines 108 and 110 that can mechanically couple with the dies 104 and 106. In examples, the trace lines 108 and 110 can be formed of a conductive material, such as copper, aluminum, or gold. The die 104 can couple with the memory substrate with a first adhesive layer 112 while the die 106 can couple with the die 104 with a second adhesive layer 114. In examples, the first and second adhesive layers 112 and 114 can be a die attach film (DAF) or a film over wire (FOW), such as available from LG Chemical headquartered in Seoul, Korea, or from AI technology located in Princeton Junction, NJ, or from Henkel AG & Co. KGaA headquartered in Dusseldorf, Germany. The semiconductor package 100 can include a mold 116 that can protect the trace 108, the first die 104, and the second die 106.

The semiconductor package 100 can also include a fillet 118, as shown with reference to FIG. 1. In examples, the fillet 118 can be formed from a capillary underfill and disposed on a top surface 120 of the solder mask 102. In the example of FIG. 1, the fillet 118 is separate and/or different from the first adhesive layer 112. The fillet 118 can be formed adjacent to and abutting a side surface 122 of the first die 104 and a side surface 124 of the first adhesive layer 114. In examples, the fillet 118 can help prevent cracks from forming in the trace line 108 or in other components or areas of the package 100. For example, in scenarios where the semiconductor package 100 does not include the fillet 118, cracking can occur in the trace line 108. In some examples, the materials used to form the dies 104 and 106 can differ from the materials used to form the trace lines 108 and 110. For example, the dies 104 and 106 can comprise silicon while the trace lines 108 and 110 can be formed from copper. Furthermore, the adhesive layers 112 and 114 can be formed from materials that are different from the materials used to the form the dies 104 and 106 or the traces 108 and 110. To further illustrate, the adhesive layers 112 and 114 can be formed from an epoxy that provides high bond strength and stability between dissimilar materials. Similarly, the material used to form the mold 116 can differ from the materials used to form the dies 104 and 106, the materials used to form the traces 108 and 110, and the materials used to the form the adhesive layers 112 and 114. For example, the mold 116 can be typically formed from epoxy resins, phenolic hardeners, silicas, catalysts, pigments, and mold release agents.

The various different materials used to form the dies 104 and 106, the trace lines 108 and 110, the adhesive layers 112 and 114, and the mold 116 can have different properties including different coefficients of thermal expansion (CTE). For example, the CTE of silicon can be 2.6 ppm/° C. while the CTE of copper can be 16.7 ppm/° C. and the CTE of the material for the mold 116 can be 10˜15 ppm/° C. below Tg and 35˜50 ppm/° C. above Tg. In addition, the CTE for the adhesive layers 112 and 114 can be in a range of 30 ppm/° C. to 230 ppm/° C. below Tg.

In addition to the different CTE values for the materials used to form the dies 104 and 106, the traces 108 and 110, the adhesive layers 112 and 114, and the mold 116, a modulus of elasticity of each of these materials can also vary. For example, the modulus of elasticity of copper can be in a range of 110 GPa to 138 GPa while the modulus of elasticity of silicon can be 165 GPa. Moreover, the modulus of elasticity of epoxy can be in a range of 1 GPa to 10 GPa and the modulus of elasticity of the mold 116 can be 19 to 30 GPa below Tg.

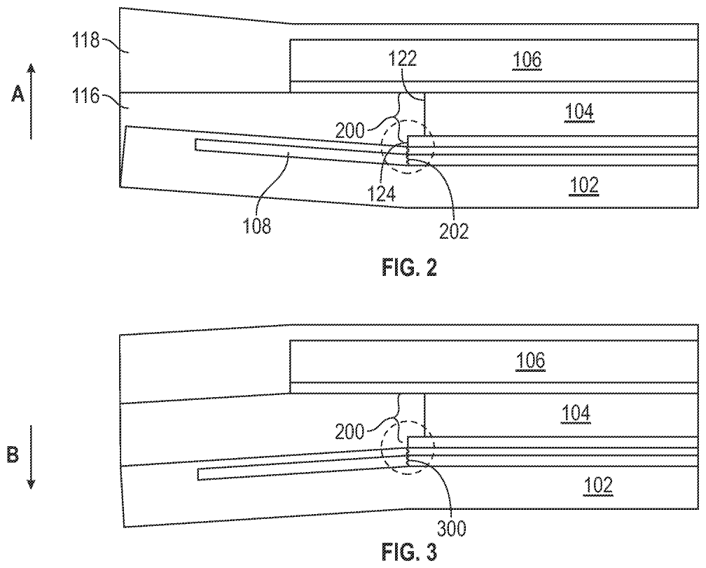

As a result of the different properties, such as CTE and modulus of elasticity, deformation can occur in the semiconductor package 100, such as in response to thermal cycles or other reliability tests, which can result in failure at a die edge 200 formed by the first die side surface 122 together with the first adhesive layer side surface 124 as shown with reference to FIGS. 2 and 3. Examples of failure can include cracking, separation, fracture, or any other type of unintended non-uniformity or discontinuity. Reliability testing can include thermal cycling of the semiconductor package 100 from −65° C. to 160° C. numerous times. Other testing that can induce failure can include life cycle testing. Other types of stresses that can lead to failure can include thermal stress, physical stress, and the like. Due to the different CTEs and the different modulus of elasticities among the dies 104 and 106, the trace lines 108 and 110, the adhesive layers 112 and 114, and the mold 116, the semiconductor package 100 can warp, which can create cracks.

To further illustrate, during thermal cycling, the semiconductor package 100 can warp along a direction A as shown in FIG. 2. When the semiconductor package 100 warps or bends or deforms along the direction A, a crack 202 can form at the die edge 200. In particular, the different CTEs and the different modulus of elasticities associated with the different materials among the dies 104 and 106, the trace lines 108 and 110, the adhesive layers 112 and 114, and/or the mold 116 can create stresses that are unabated. As such, the disparity among the different CTEs and the different modulus of elasticities and the accompanying stresses created by the disparities can cause the warping (e.g., along the direction A), which in turn can cause the crack 202.

Similarly, during thermal cycling, the semiconductor package 100 can warp along a direction B as shown with reference to FIG. 3. When the semiconductor package 100 warps along the direction B, a crack 300 can form at, adjacent, near, or proximal to the die edge 200. Again, the different CTEs and the different modulus of elasticities associated with the different materials among the dies 104 and 106, the trace lines 108 and 110, the adhesive layers 112 and 114, and/or the mold 116 can create stresses that are unabated. As such, the disparity among the different CTEs and the different modulus of elasticities and the accompanying stresses created by the disparities can cause the warping along the direction B, which can result in the crack 300.

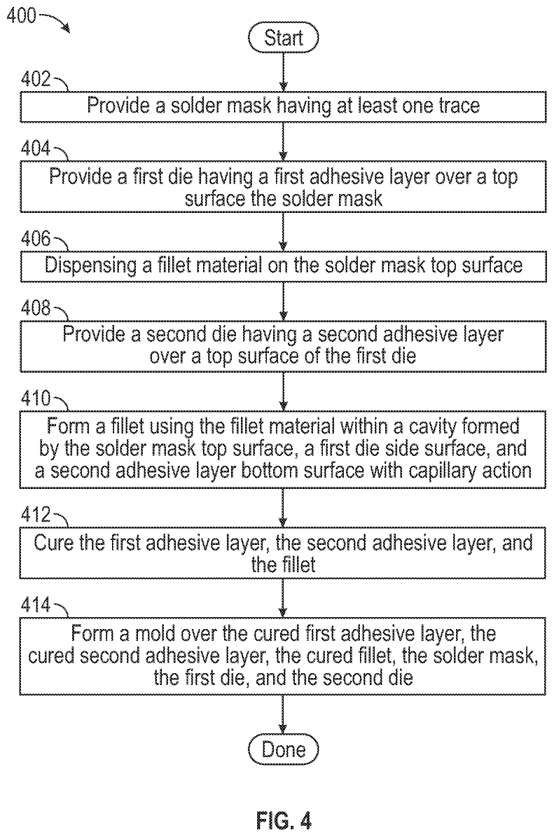

As noted above, examples of the semiconductor package 100 can include the fillet 118. The fillet 118 can function to prevent the formation of the cracks 202 and 300 when the semiconductor package 100 is subject to stress. In particular, the fillet 118 can be formed from an underfill material such that the fillet 118 can absorb the stresses created by the different CTEs and the different modulus of elasticities. In addition, a fillet in accordance with examples can be formed from a material that includes carbon nanotubes. When a fillet is formed using a carbon nanotube material, the fillet can absorb the stresses created by the different CTEs and the different moduli of elasticity. The fillet can be formed in the semiconductor package 100 using various techniques, as described with reference to FIG. 4.

Now making reference to FIG. 4, a method 400 for forming the semiconductor package 100 is shown in accordance with examples. In FIG. 4, the fillet can be formed from a capillary underfill. Initially, during an operation 402, a solder mask having at least one trace is provided. The at least one trace can be formed using any type of printed circuit board fabrication technique, such as a subtractive process where a copper sheet is covered with a photoresist and portions of the photoresist corresponding to the at least one trace are exposed to light. Moreover, the unexposed photoresist can be washed away with solvent where an etching step is then performed. After etching, the exposed photoresist can be washed away with another solvent that does not attack the at least one trace.

The solder mask can be formed of a polymer layer that coats the at least one trace. The solder mask can be formed by silkscreening an epoxy liquid through a pattern. In other examples, liquid photoimageable solder mask inks or dry film photoimageable solder masks can be used.

After the solder mask having at least one trace is provided during the operation 402, a first die is provided over the solder mask via a first adhesive layer during an operation 404. In examples, a die can be formed with an adhesive layer such that a first die can be provided onto the solder mask using the first adhesive layer. The die can have a side that is grinded and the adhesive layer can be applied to the side of the die that is grinded. Dicing tape can be provided with an adhesive layer deposited on a surface of the dicing tape. The dicing tape can include a dicing film. The die can be placed on the adhesive layer and then the resulting bi-layered structure, i.e., the die coupled with the adhesive layer, can be diced to form a first die on a first adhesive layer. During the operation 404, the formed first die on the first adhesive layer can be provided on the solder mask using a die attach machine.

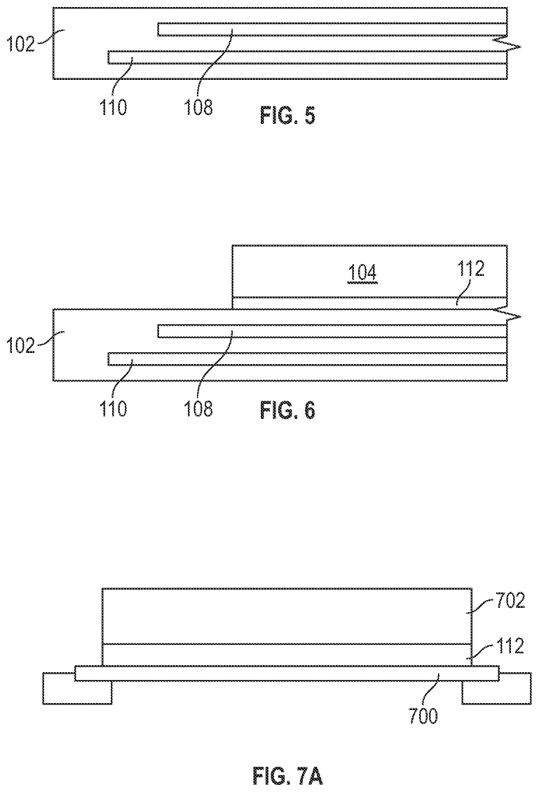

As an example of the method 400 and referred to herein as the “first illustration,” reference is made to FIGS. 5-7B where, during the operation 402, the solder mask 102 is provided (FIG. 5). In the first illustration, the solder mask 102 can be provided by first forming the trace lines 108 and 110 with a subtractive process as discussed above. The solder mask 102 is then formed over the trace lines 108 and 110 with an epoxy liquid using a silkscreening process. After the solder mask 102 is provided during the operation 402, the operation 404 is performed in the first illustration.

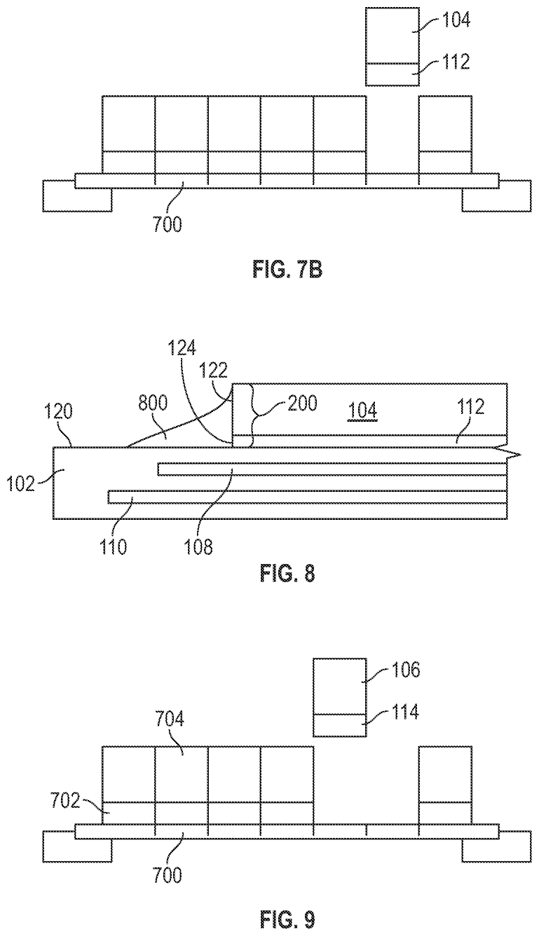

During the operation 404, the first die 104 and the first adhesive layer 112 are formed on the solder mask 102, as shown with reference to FIG. 6. In the first illustration, the first die 104 can be formed on the first adhesive layer 112 as shown with reference to FIGS. 7A and 7B. In this example, dicing tape 700 having the adhesive layer 112 is provided. Moreover, a die 702 is placed onto the adhesive layer 122 as shown with reference to FIG. 7A. Then, the resulting bi-lateral structure having the die 704 and the adhesive layer 112 is diced as shown with reference to FIG. 7B. In the first illustration, any suitable technique can be used to dice the die 704 and the adhesive layer 702 and cut into a first portion of the dicing tape 700, for example without completely cutting through the dicing tape 700, such as using a blade, a laser, or other cutting device. After the first die 104 is formed on the first adhesive layer 112 as shown with reference to FIGS. 7A and 7B, the first die 104 and the first adhesive layer 112 can be formed on the solder mask 102 using a die attach machine during the operation 404.

Returning attention to FIG. 4 and the method 400, after the first die is provided during the operation 404, the method 400 can perform an operation 406 that can include dispensing a fillet material on the solder mask top surface. As noted above, the method 400 can relate to using a capillary underfill. Thus, the fillet material can correspond to a capillary underfill. In examples, when the fillet material is dispensed on the solder mask top surface, the fillet material can be dispensed at a die edge formed by a side of the first die and a side of the adhesive layer. The fillet material can be dispensed using any technique suitable for dispensing a material that is capable of being cured, such as epoxy. For example, the fillet material can be dispensed on the solder mask top surface using fluid dispensing equipment for printed circuit boards. The fluid dispensing machine can include a needle that dispenses the filler material at the solder mask top surface. In examples, the fluid dispensing machine can also dispense the fillet material at the die edge. Any type of fluid dispensing machine can be used, such as the Quantum line of dispensing machines available from Asymtek™ and the Nordson™ Corporation located in Westlake, Ohio.

Returning to the first illustration and making reference to FIG. 8, at operation 406, a fluid dispensing machine (not shown) can dispense capillary underfill 800 on the solder mask top surface 120. In the first illustration, a fluid dispensing machine can dispense the capillary underfill 800 at the die edge 200 defined by the first die side surface 122 and the first adhesive side 124.

After the capillary underfill 800 has been dispensed during the operation 406, the method 400 can perform an operation 408, as shown with regards to FIG. 4. During the operation 408, a second die can be provided over a top surface of the first die via a second adhesive layer. As discussed above, a die can be formed with an adhesive layer such that a second die can be provided onto the solder mask using the second adhesive layer. The die can have a side that is grinded where the adhesive layer can be applied to the side of the die that is grinded. Dicing tape can be provided with an adhesive layer deposited on a surface of the dicing tape. The dicing tape can also include a dicing film. The die can be placed on the adhesive layer and then the resulting bi-layered structure, i.e., the die coupled with the adhesive layer, can be diced to form a second die on a second adhesive layer. During the operation 408, the second die formed on the second adhesive layer can be provided on a top surface of the first die using a die attach machine.

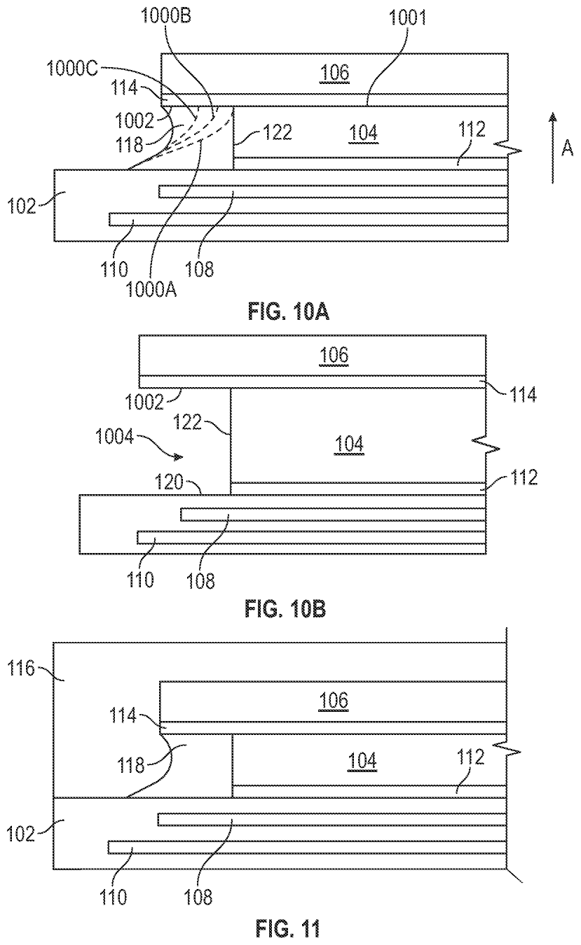

Turning back to the first illustration, the second die 106, such as provided on the second adhesive layer 114, can be separated from other dies of the wafer when the adhesive layer 702 and the die 704 are diced, as discussed above and shown with reference to FIG. 9. After formation of the second die 106 having the second adhesive layer 114, the second die 106 having the second adhesive layer 114 can be provided on a top surface 1001 of the first die 104, as shown with reference to FIG. 10A.

After the second die with the second adhesive layer has been provided on the top surface of the first die, an operation 410 is performed, as shown with reference to FIG. 4. At operation 410, a fillet is formed using the fillet material with capillary action. In examples, the fillet can be formed within a cavity formed by the solder mask top surface, the first die side surface, and a bottom surface of the second adhesive layer. Capillary action occurs when a combination of surface tensions and adhesive forces propel a liquid. Surface tension can be caused by cohesion within the liquid while the adhesive forces can relate to forces between the liquid and a crucible, such as the cavity formed by the solder mask top surface, the first die side surface, and the second adhesive layer bottom surface, within which the liquid is disposed.

With continued reference to the method 400 and after the fillet is formed in the cavity, the first adhesive layer, the second adhesive layer, and fillet can be subjected to a curing process during an operation 412. During the curing process, the capillary underfill, which can be in liquid form when it is dispensed, can be hardened. In examples, the curing process can be performed at a temperature of 150° C. for approximately two hours. In examples, the curing process can increase a modulus of elasticity associated with the fillet 118, thereby increasing the ability of the fillet 118 to resist cracking from occurring in the trace line 108, as discussed above. Furthermore, the curing process can increase cross-linking of the material of the capillary underfill, such as in instances where the capillary underfill is formed from epoxy.

Returning to the first illustration along with FIGS. 10A and 10B, during the operation 410, the capillary underfill 800 can move along the first die side surface 122 as shown at 1000A-1000C via capillary action. In the first illustration, the capillary underfill 800 can continue movement until the fillet 118 is formed, as shown with reference to FIG. 10A. More specifically, capillary action can cause the capillary underfill 800 to flow upwardly along the direction A along the first die side 112 and towards a bottom surface 1002 of the second adhesive layer 114. In examples, after the capillary underfill 800 contacts the second adhesive layer bottom surface 1000, the fillet 118 is formed. In the first illustration, the solder mask top surface 120, the first die side surface 122, and the second adhesive layer bottom surface 1002 can form a cavity 1004, as shown with reference to FIG. 10B, which is an illustration without the fillet 118. In examples, the fillet 118 can be disposed in the cavity 1004. Afterwards, in the first illustration, the fillet 118 along with the adhesive layers 112 and 114 are cured, e.g., at a temperature of 150° C. for two hours during a curing operation 412.

Upon formation of the fillet 118 in the operation 410 and curing of the fillet 118 along with curing of the first adhesive layer 112 and the second adhesive layer 114 during the operation 412, the method 400 can perform an operation 414. In the operation 414, a mold is formed over all or a portion of the cured first and second adhesive layers, the cured fillet, the solder mask, and the first and second dies. In examples, the mold can be formed using any suitable techniques, including compression molding and transfer molding. The mold can seal the semiconductor package formed by the at least one trace, the first and second dies, the first and second adhesive layers, and the fillet. In an example, the mold can electrically insulate the at least one trace, the first and second dies, the first and second adhesive layers, and the fillet.

Returning to the first illustration and FIG. 11, the mold 116 can be formed with a compression molding technique. In the first illustration, the mold 116 can be formed over the traces 108 and 110, the first and second dies 104 and 106, the first and second adhesive layers 112 and 114, and the fillet 118, as shown with reference to FIG. 11. Upon formation of the mold 116, the method 400 is complete.

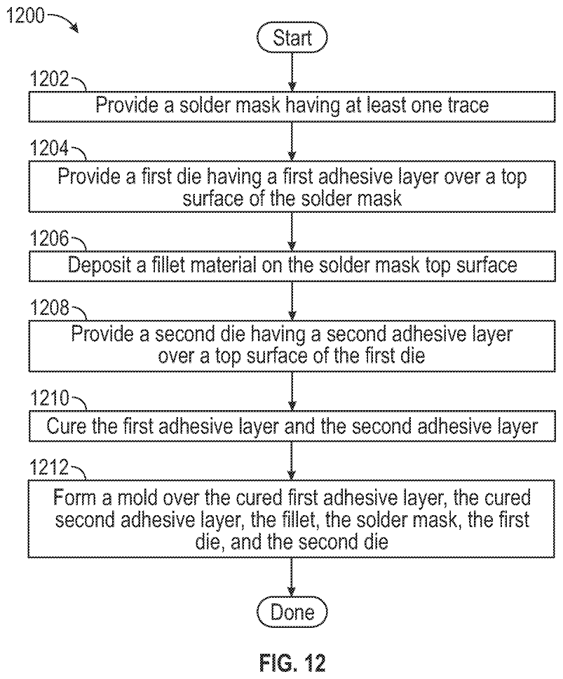

In the example of FIG. 4, the fillet 118 is formed with a capillary underfill. The capillary underfill can include a carbon nanotube material. The carbon nanotube material can include a suspension of carbon nanotube fragments having a nanotube concentration of about 1.3 g/cm³ to about 2.6 g/cm³. Now making reference to FIG. 12, a method 1200 is shown relating to the formation of a fillet with a carbon nanotube material for a semiconductor package, in accordance with some examples. Initially, at operation 1202, a solder mask having at least one trace is provided as detailed above with reference to the operation 402. After the solder mask having at least one trace is provided during the operation 1202, a first die is provided over the solder mask via a first adhesive layer during an operation 1204 as detailed above with reference to the operation 404.

As an example of the method 1200 and referred to herein as the “second illustration,” reference again is made to FIGS. 5-7B where, during the operation 1202, the solder mask 102 is provided. In the second illustration, the solder mask 102 can be provided by first forming the trace lines 108 and 110 with a subtractive process as discussed above. The solder mask 102 is then formed over the trace lines 108 and 110 with an epoxy liquid using a silkscreening process. After the solder mask 102 is provided during the operation 1202, the operation 1204 is performed in the second illustration.

During the operation 1204, the first die 104 and the first adhesive layer 112 are formed on the solder mask 102, as shown with reference to FIG. 6. In the second illustration, the first die 104 can be formed on the first adhesive layer 112 as shown with reference to FIGS. 7A and 7B and as detailed above. Then, the resulting bi-lateral structure having the die 704 and the adhesive layer 702 is diced as shown with reference to FIG. 7B also as detailed above. In the second illustration, any suitable technique can be used to dice the die 704 and the adhesive layer 702 and cut into a first portion of the dicing tape 700 without completely cutting through the dicing tape 700. After the first die 104 is formed on the first adhesive layer 112 as shown with reference to FIGS. 7A and 7B, the first die 104 and the first adhesive layer 112 can be provided on the solder mask 102 using a die attach machine during the operation 1204.

Returning attention to FIG. 12, after completion of the operation 1204, the method 1200 includes an operation 1206, where a fillet material is dispensed on a solder mask top surface. In some examples, during the operation 1206, in addition to dispensing the fillet material on the solder mask top surface, the fillet material can be dispensed adjacent to and abutting the first die side. In FIG. 12, the fillet material can comprise or use one or more carbon nanotubes. Here, during the operation 1206, a printer, such as a three-dimensional printer, which can include an inkjet-type printer, can be used to dispense the fillet material onto the solder mask top surface and, if desired, adjacent to and abutting the first die side. In examples, the printer can be programmed to provide some of the fillet material onto the solder mask top surface and, if desired, adjacent to and abutting the first die side. To further illustrate, the printer can be controlled to dispense fillet material in a pattern such as having a rectilinear shape, such as a rectangle or a square, an ovoid shape, a circular shape, or any type of polygon.

In further examples, additive manufacturing techniques can be employed to dispense the fillet material onto the solder mask top surface and, if desired, adjacent to and abutting the first die side when the fillet material includes carbon nanotubes. Here, the fillet material can be dispensed through the accumulation of successive layers of carbon nanotube materials.

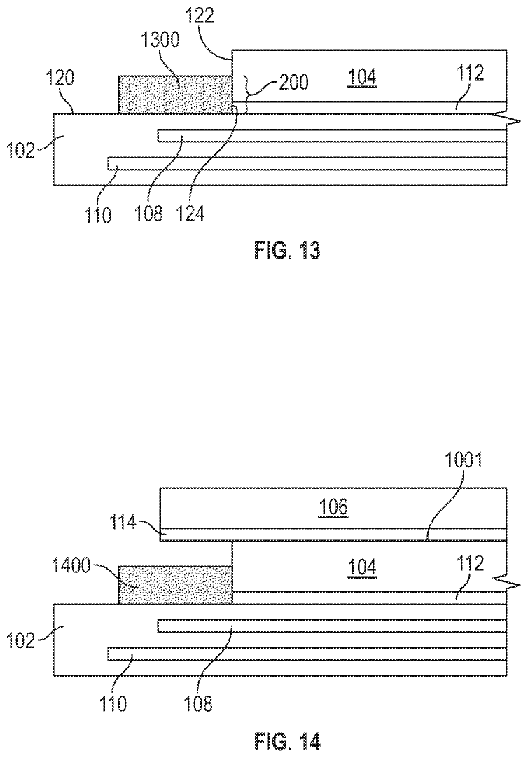

Returning to the second illustration and FIG. 13, during the operation 1206, a printer (not shown) is controlled to dispense fillet material 1300 having a rectilinear shape. Moreover, in the second illustration, the fillet material 1300 is dispensed such that the fillet material 1300 is on the top surface 120 and adjacent to and abutting the first die side surface 122 and the first adhesive layer side surface 124. Thus, the fillet material 1300 is disposed on the top surface 120 and adjacent to and abutting the die edge 200 to form the fillet 1400 (FIG. 14). In some examples, the fillet 1400 can extend up to the second adhesive layer bottom surface 1002.

In FIG. 12, after the fillet material has been dispensed during the operation 1206, the method 1200 performs an operation 1208. During the operation 1208, a second die can be provided over a top surface of the first die via a second adhesive layer as discussed above with reference to the operation 408.

Turning back to the second illustration, the second die 106 formed on the second adhesive layer 114 can be formed when the adhesive layer 702 and the die 704 are diced, as discussed above and shown with reference to FIG. 9. After formation of the second die 106 having the second adhesive layer 114, the second die 106 having the second adhesive layer 114 can be provided on the top surface 1001 of the first die 104 with a die attach machine (not shown), as shown with reference to FIG. 14.

In FIG. 12, after the second die is provided on the second adhesive layer during the operation 1208, the method 1200 performs an operation 1210, where the first adhesive layer and the second adhesive layer are cured. In examples, the first and second adhesive layers can be cured at a temperature of 150° C. for two hours.

After the curing process is complete, the method 1200 can include, at operation 1212, forming a mold over one or more of the fillet, the cured first and second adhesive layers, the solder mask, and the first and second dies as detailed above with reference to the operation 414.

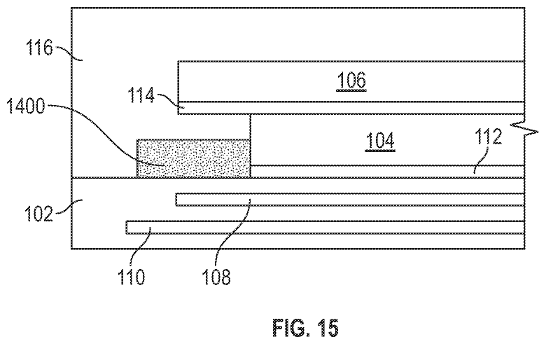

Returning to the second illustration and FIG. 15, the mold 116 can be formed with a compression molding technique. In the second illustration, the mold 116 can be formed over the trace lines 108 and 110, the first and second dies 104 and 106, the first and second adhesive layers 112 and 114, and the fillet 1400, as shown with reference to FIG. 15. Upon formation of the mold 116, the method 1200 is completed.

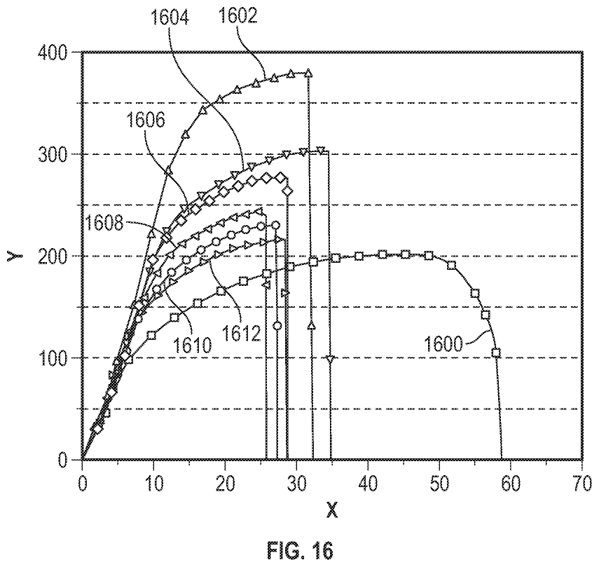

As noted above, by implementing either the fillet 118 or the fillet 1400, the ability of the semiconductor package 100 to resist cracking at the line trace 108 is greatly diminished. In examples, the fillet can be formed using a capillary underfill, such as using epoxy, or using a carbon nanotube material. In examples where the fillet is formed with carbon nanotubes, such as the fillet 1400, the fillet 1400 has higher tensile strength and plasticity in comparison to the traces 108, as shown with reference to FIG. 16.

FIG. 16 illustrates stress-strain curves where the modulus of elasticity of the fillet 1400 formed with various concentrations of carbon nanotubes is compared with a trace line formed of copper. In FIG. 16, the x-axis can correlate to strain, where the numerical values listed along the x-axis can correspond to an percent of engineering strain. In FIG. 16, the y-axis can correspond to engineering stress, where the values listed along the y-axis can correspond to megapascals (MPa).

In FIG. 16, line 1600 corresponds to a stress/strain curve associated with a trace line formed of pure copper. In examples where the fillet material comprises carbon nanotube material, the fillet material can include different compositions that can have different combinations of carbon nanotubes, titanium diboride (TiB₂), and copper. Line 1602 corresponds to a stress/strain curve for a fillet, such as the fillet 1400, that is formed from a first composition having one part carbon nanotube, four parts TiB₂, and one part copper. Line 1604 corresponds to a stress/strain curve for a fillet, such as the fillet 1400, that is formed from a composition having one part carbon nanotube and one part copper while line 1606 corresponds to a stress/strain curve for a third composition having two parts carbon nanotube, three parts TiB₂, and one part copper. In the example of FIG. 16, line 1608 corresponds to a stress/strain curve for a fourth composition having four parts carbon nanotube, one part TiB₂, and one part copper and line 1610 corresponds to a stress/strain curve for a fifth composition having five parts TiB₂ and one part copper. Line 1612 corresponds to a stress/strain curve for a sixth composition having four parts TiB₂ and one part copper.

As may be seen with reference to FIG. 16, the use of carbon nanotubes in a fillet material greatly increases the tensile strength and plasticity of structures implementing them. In particular, the slopes corresponding with each of the lines 1600-1612 can relate to a modulus of elasticity for the material that corresponds to the lines. In particular, higher slopes can correspond to higher stress resistance, which can contribute to a greater rigidity for the structure having the fillet material associated with the slope. For example, for the line 1602 corresponding to one part carbon nanotube, four parts TiB₂, and one part copper, has a higher slope in comparison to the other compositions represented by the lines 1600 and 1604-1612 and thus provides greater rigidity. Thus, using the fillet 1400, and particularly a fillet that comprises carbon nanotubes, can help minimize cracking associated with trace lines as discussed above.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense. Moreover, various features described herein can be combined with other features described herein while still achieving the goals of the present disclosure.

What is claimed is:

1. A semiconductor package comprising:
at least one conductive trace line disposed within a solder mask, the solder mask having a top surface;
a first die disposed over the solder mask and mechanically coupled with the at least one trace line, the first die having a side surface;
a first adhesive disposed between the at least trace line and the first die, the first adhesive having a side surface, wherein the first die side surface and the first adhesive define a die edge;
a fillet disposed adjacent the die edge;
a second die disposed above the first die; and
a second adhesive disposed between the first die and the second die, the second adhesive having a bottom surface, wherein the solder mask top surface, the first die side surface, and the second adhesive bottom surface define a cavity and the fillet is disposed within the cavity.

2. The semiconductor package of claim 1, wherein the fillet is a capillary underfill comprising an epoxy resin.

3. The semiconductor package of claim 2, wherein the capillary underfill extends from the solder mask top surface to the second adhesive bottom surface such that the capillary underfill contacts the solder mask top surface and the second adhesive bottom surface.

4. The semiconductor package of claim 2, wherein the capillary underfill contacts the first die side surface and extends along the first die side surface.

5. The semiconductor package of claim 1, wherein the fillet comprises a fillet material comprising carbon nanotubes.

6. The semiconductor package of claim 5, wherein the fillet extends from the solder mask top surface and along the first die side surface such that the fillet contacts the solder mask top surface and the first die side surface.

7. The semiconductor package of claim 1, wherein the fillet is different from the first adhesive.

8. A method of forming a semiconductor package, the method comprising:
providing a solder mask having at least one conductive trace line disposed therein;
providing a first die having a first adhesive at a top surface of the solder mask, the first die having a side surface and the first adhesive having a side surface, wherein the first die side surface and the first adhesive side surface define a die edge;
dispensing a fillet material on the solder mask top surface at the die edge; and
providing a second die having a second adhesive at a top surface of the first die, the second adhesive having a bottom surface, wherein the solder mask top surface, the first die side surface, and the second adhesive bottom surface define a cavity, where the fillet material is disposed within the cavity.

9. The method of claim 8, wherein the fillet material is a capillary underfill comprising an epoxy resin and the fillet is disposed within the cavity via capillary action upon dispensing the fillet material on the solder mask top surface and the die edge.

10. The method of claim 9, wherein the capillary underfill extends from the solder mask top surface to the second adhesive bottom surface such that the capillary underfill contacts the solder mask top surface, the second adhesive bottom surface, and the first die side surface wherein the capillary underfill extends along first die side surface.

11. The method of claim 8, further comprising curing the semiconductor package after providing the second die on the second adhesive.

12. The method of claim 8, wherein the fillet material comprises carbon nanotubes and the fillet material is dispensed with a printer.

13. The method of claim 12, wherein the carbon nanotube extends from the solder mask top surface and along the first die side surface such that the fillet contacts the solder mask top surface and the first die side surface.

14. The method of claim 8, wherein the fillet material is different from the first adhesive.

15. A semiconductor package comprising:
at least one conductive trace line disposed within a solder mask, the solder mask having a top surface;
a first die disposed over the solder mask and mechanically coupled with the at least one trace line, the first die having a side surface;
a first adhesive disposed between the at least trace line and the first die, the first adhesive having a side surface, wherein the first die side surface and the first adhesive define a die edge;
a fillet disposed adjacent the die edge and extending from the die edge along the solder mask top surface away from the die edge, wherein the fillet covers the die edge and at least a portion of an exposed top surface of the first adhesive;
a second die disposed above the first die; and
a second adhesive disposed between the first die and the second die, the second adhesive having a bottom surface, wherein the solder mask top surface, the first die side surface, and the second adhesive bottom surface define a cavity and the fillet is disposed within the cavity at the die edge.

16. The semiconductor package of claim 15, wherein the fillet is a capillary underfill comprising an epoxy resin.

17. The semiconductor package of claim 16, wherein the capillary underfill extends from the solder mask top surface to the second adhesive bottom surface such that the capillary underfill contacts the solder mask top surface and the second adhesive bottom surface and the capillary underfill is in contact with the first die side surface and extends along first die side surface.

18. The semiconductor package of claim 15, wherein the fillet is a carbon nanotube.

19. The semiconductor package of claim 18, wherein the fillet extends from the solder mask top surface and along the first die side surface such that the fillet contacts the solder mask top surface and the first die side surface.

20. The semiconductor package of claim 15, wherein the fillet is separate from the first adhesive.
